(19) United States
(12) Patent Application Publication
(10) Pub. No.: US 2021/0159414 A1
(43) Pub. Date: May 27, 2021

(54) METHOD FOR PRODUCING VAPOR DEPOSITION MASK, VAPOR DEPOSITION MASK PRODUCING APPARATUS, LASER MASK AND METHOD FOR PRODUCING ORGANIC SEMICONDUCTOR ELEMENT

(71) Applicant: Dai Nippon Printing Co., Ltd., Tokyo (JP)

(72) Inventors: Yoshiko MIYADERA, Tokyo (JP); Takayoshi NIRENGI, Tokyo (JP); Toshihiko TAKEDA, Tokyo (JP)

(73) Assignee: Dai Nippon Printing Co., Ltd., Tokyo (JP)

(21) Appl. No.: 17/166,370

(22) Filed: Feb. 3, 2021

Related U.S. Application Data
(62) Division of application No. 15/546,710, filed on Jul. 27, 2017.

(30) Foreign Application Priority Data
Feb. 3, 2015 (JP) 2015-019665
Feb. 2, 2016 (JP) 2016-018161

(51) Int. Cl. H01L 51/00; B23K 26/382; C23C 14/04

(52) U.S. Cl. CPC H01L 51/0011; B23K 26/382; H01L 51/56; H01L 51/001; C23C 14/042

(57) ABSTRACT

A step of preparing a resin plate-equipped metal mask including a metal mask in which a slit is provided and a resin plate, and a step of laser irradiation from the metal mask side to form an opening corresponding to a pattern to be produced by vapor deposition in the resin plate are included, wherein in the step of forming the opening, by using a laser mask in which an opening region corresponding to the opening and an attenuating region that is positioned in a periphery of the opening region and attenuates energy of the laser, the opening corresponding to the pattern to be produced by vapor deposition is formed with respect to the resin plate with the laser that passes through the opening region, and a thin part is formed in a periphery of the opening of the resin plate with the laser that passes through the attenuating region.

### CROSS REFERENCE TO RELATED APPLICATION

This application is a division of U.S. application Ser. No. 15/546,710, filed Jul. 27, 2017, which in turn is the National Stage entry of International Application No. PCT/JP2016/053145, filed Feb. 3, 2016, the entireties of which are incorporated herein by reference.

### FIELD OF THE INVENTION

Embodiments of the present invention relate to a method for producing a vapor deposition mask, a vapor deposition mask producing apparatus, laser mask and a method for producing an organic semiconductor element.

### BACKGROUND OF THE INVENTION

With upsizing of the products using organic EL elements or increase in substrate sizes, a demand for upsizing is also growing with respect to vapor deposition masks, and the metal plates for use in production of the vapor deposition masks constituted of metals are also upsized. However, with the present metal processing technique, it is difficult to form openings in a large metal plate with high precision, which cannot respond to enhancement in definition of the openings.

Moreover, in the case of a vapor deposition mask constituted of only a metal, the mass thereof also increases with upsizing, and the total mass including a frame also increases, which becomes a hindrance to handling.

Under such circumstances, in Patent Document 1, there is proposed a method for producing a vapor deposition mask including a metal mask in which slits are provided and a resin mask which is positioned on the surface of the metal mask and in which openings corresponding to a pattern to be produced by vapor deposition are arranged for a plurality of rows in the lengthwise direction and in the crosswise direction, the metal mask and the resin mask being stacked. The method for producing the vapor deposition mask proposed in Patent Document 1 is regarded as being capable of producing the vapor deposition mask that satisfies both high definition and lightweight in upsizing.

Moreover, Patent Document 1 above discloses that in order to suppress generation of a shadow in production by vapor deposition using a vapor deposition mask, the sectional shape of the opening or the sectional shape of the slit is preferably a shape having broadening toward the vapor deposition source side. Notably, the shadow is a phenomenon that a part of a vapor deposition material released from a vapor deposition source collides with inner wall surfaces of the slit of the metal mask and/or the opening of the resin mask and does not reach the vapor deposition target, and thereby, a portion without vapor deposition that has a film thickness smaller than the intended vapor deposition film thickness arises.

### CITATION LIST

### Patent Document

### Patent Document 1: Japanese Patent No. 5288073

### SUMMARY OF THE INVENTION

### Technical Problem

An object of an embodiment of the present invention is a further improvement of the method for producing a vapor deposition mask proposed in Patent Document 1 above, and a primary object thereof is to provide a method for producing a vapor deposition mask and a vapor deposition mask producing apparatus capable of achieving lightweight even when upsized and capable of forming a vapor deposition pattern with higher definition than a conventional one by suppressing generation of a so-called shadow, further, a laser mask used in these producing method and producing apparatus, and furthermore, a method for producing an organic semiconductor element capable of producing an organic semiconductor element with higher definition than a conventional one.

### Solution to Problem

There is provided a method for producing a vapor deposition mask according to an embodiment of the present invention, including: a step of preparing a resin plate-equipped metal mask including a metal mask in which a slit is provided and a resin plate, the metal mask and the resin plate being stacked; and a step of performing irradiation with a laser from the metal mask side to form an opening corresponding to a pattern to be produced by vapor deposition in the resin plate, wherein in the step of forming the opening, by using a laser mask in which an opening region corresponding to the opening, and an attenuating region that is positioned in a periphery of the opening region and attenuates energy of the laser of the irradiation are provided, the opening corresponding to the pattern to be produced by vapor deposition is formed with respect to the resin plate with the laser that passes through the opening region, and a thin part is formed in a periphery of the opening of the resin plate with the laser that passes through the attenuating region.

In the aforementioned method for producing a vapor deposition mask, a transmittance of the laser in the attenuating region of the laser mask used in the step of forming the opening may be about 50% or less.

Moreover, there is provided a vapor deposition mask producing apparatus according to an embodiment of the present invention for producing a vapor deposition mask including a metal mask in which a slit is provided and a resin mask in which an opening corresponding to a pattern to be produced by vapor deposition is provided, the metal mask and the resin mask being stacked, the vapor deposition mask producing apparatus including a device that performs irradiation with a laser from the metal mask side with respect to a resin plate-equipped metal mask including a metal mask in which a slit is provided and a resin plate, the metal mask and the resin plate being stacked to form an opening corresponding to a pattern to be produced by vapor deposition in the resin plate, wherein in the device which forms the opening, a laser mask in which an opening region corresponding to the opening, and an attenuating region that is positioned in a periphery of the opening region and attenuates energy of the laser of the irradiation are provided is used, and the opening corresponding to the pattern to be produced by vapor deposition is formed with respect to the resin plate with the laser that passes through the opening region, and a thin part is formed in a periphery of the opening of the resin plate with the laser that passes through the attenuating region.

In the aforementioned vapor deposition mask producing apparatus, a transmittance of the laser in the attenuating region of the laser mask used in the step of forming the opening may be about 50% or less.

Moreover, there is provided a laser mask according to an embodiment of the present invention, used in forming an opening of a resin mask with a laser when producing a vapor deposition mask including a metal mask in which a slit is provided and the resin mask in which the opening corresponding to a pattern to be produced by vapor deposition is provided, the laser mask including: an opening region corresponding to the opening; and an attenuating region that is positioned in a periphery of the opening region and attenuates energy of the laser of irradiation.

In the aforementioned laser mask, a transmittance of the laser in the attenuating region may be about 50% or less.

Moreover, there is provided a method for producing an organic semiconductor element according to an embodiment of the present invention, including a vapor deposition pattern forming step of forming a vapor deposition pattern on a vapor deposition target using a vapor deposition mask, wherein in the vapor deposition pattern forming step, the vapor deposition mask produced by the aforementioned method for producing a vapor deposition mask of an embodiment of the present invention is used.

### Advantageous Effects

According to the method for producing a vapor deposition mask according to an embodiment of the present invention, the vapor deposition mask producing apparatus according to an embodiment of the present invention, and the laser mask according to an embodiment of the present invention, a vapor deposition mask capable of achieving light weight even when upsized and capable of forming a vapor deposition pattern with higher definition than a conventional one by suppressing generation of a so-called shadow can be produced. Moreover, according to the method for producing an organic semiconductor element of an embodiment of the present invention, organic semiconductor elements with higher definition than a conventional one can be produced.

### BRIEF DESCRIPTION OF THE DRAWINGS

FIGS. 1A to 1D are step diagrams for explaining a method for producing a vapor deposition mask according to an embodiment of the present invention.

FIG. 2 is an elevation view of a laser mask used in the method for producing a vapor deposition mask of an embodiment of the present invention.

FIGS. 3A to 3N are expanded elevation views of various laser masks for explaining specific modes of an opening region and an attenuating region.

FIG. 4 is an elevation view of the vapor deposition mask of Embodiment (A) as seen from the metal mask side.

FIG. 5 is an elevation view of the vapor deposition mask of Embodiment (A) as seen from the metal mask side.

FIG. 6 is an elevation view of the vapor deposition mask of Embodiment (A) seen from the metal mask side.

FIGS. 7A and 7B present elevation views of the vapor deposition mask of Embodiment (A) as seen from the metal mask side.

FIG. 8 is an elevation view of the vapor deposition mask of Embodiment (B) as seen from the metal mask side.

FIG. 9 is an elevation view of the vapor deposition mask of Embodiment (B) as seen from the metal mask side.

FIG. 10 is an elevation view exemplarily showing a frame-equipped vapor deposition mask.

FIG. 11 is an elevation view exemplarily showing a frame-equipped vapor deposition mask.

FIGS. 12A to 12C are elevation views exemplarily showing a frame.

FIG. 13 is an explanatory drawing of a mask imaging method of a reducing projection optical system.

FIG. 14 is an expanded elevation view of the laser mask for explaining relation between the opening region and the attenuating region.

FIG. 15 is a sectional picture of a resin plate in which openings and thin parts are formed using a laser mask of Embodiment 1.

FIG. 16 is a sectional picture of a resin plate in which openings and thin parts are formed using a laser mask of Embodiment 2.

FIG. 17 is a sectional picture of a resin plate in which openings and thin parts are formed using a laser mask of Embodiment 3.

FIG. 18 is a sectional picture of a resin plate in which openings and thin parts are formed using a laser mask of Embodiment 4.

FIG. 19 is a sectional picture of a resin plate in which openings and thin parts are formed using a laser mask of Embodiment 5.

FIG. 20 is a sectional picture of a resin plate in which openings and thin parts are formed using a laser mask of Embodiment 6.

FIG. 21 is a sectional picture of a resin plate in which openings and thin parts are formed using a laser mask of Embodiment 7.

FIG. 22 is a sectional picture of a resin plate in which openings and thin parts are formed using a laser mask of Embodiment 8.

FIG. 23 is a sectional picture of a resin plate in which openings and thin parts are formed using a laser mask of Embodiment 9.

FIGS. 24A to 24C show cross-sectional views of laser masks according to an embodiment of the present invention.

FIGS. 25A to 25F are cross-sectional views of a vapor deposition mask of Embodiment (C).

### DETAILED DESCRIPTION OF THE INVENTION

Hereafter, embodiments of the present invention are described with reference to the drawings and the like. It should be noted that embodiments of the present invention can be implemented in many different modes and are not construed to be limited to the contents of the description of the embodiments exemplified below. Moreover, while the drawings are sometimes schematically presented as to the widths, thicknesses, shapes and the like of individual parts as compared with the actual modes in order to more clarify the description, these are merely exemplary but do not limit interpretation of the embodiments of the present invention. Moreover, in the present specification and the drawings, elements similar to the previously mentioned ones regarding the previously mentioned drawings are sometimes given the same signs to properly omit their detailed description. Moreover, while for convenience of the description, the description is sometimes made using terms such as upward and downward, the upward direction and the downward direction may be reversed.

### (Method for Producing Vapor Deposition Mask)

Hereafter, a method for producing a vapor deposition mask according to an embodiment of the present invention is described using the drawings.

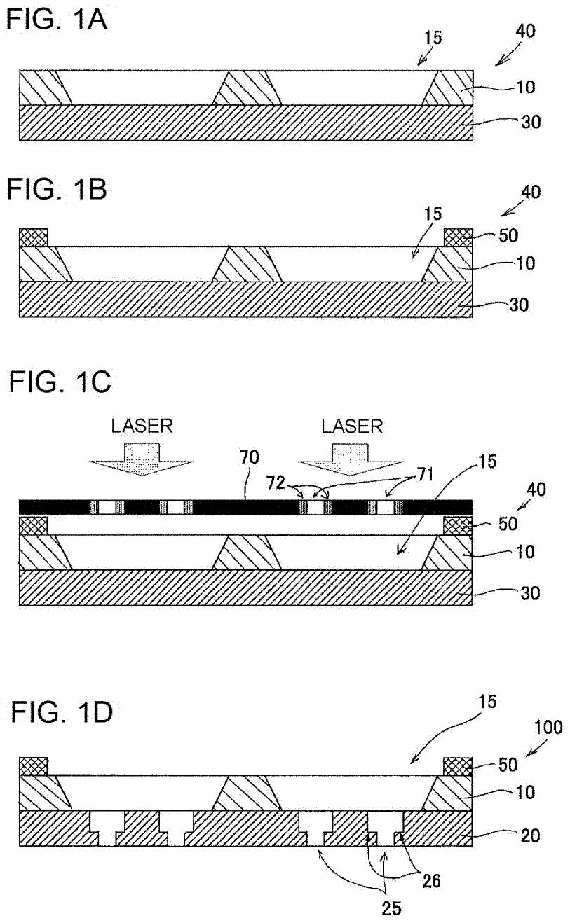

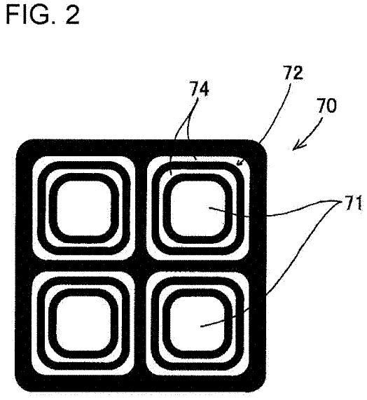

FIGS. 1A to 1D are step diagrams for explaining the method for producing a vapor deposition mask according to the embodiment of the present invention. Notably, all the portions (A) to (D) are cross-sectional views.

The method for producing a vapor deposition mask according to the present embodiment includes a step of preparing a resin plate-equipped metal mask including a metal mask in which a slit is provided and a resin plate, the metal mask and the resin plate being stacked, a step of fixing the prepared resin plate-equipped metal mask to a frame, and a step of performing irradiation with a laser from the metal mask side to form an opening corresponding to a pattern to be produced by vapor deposition in the resin plate. Hereafter, the individual steps are described.

### (Step of Preparing Resin Plate-Equipped Metal Mask)

As shown in FIG. 1A, this step is a step of preparing a resin plate-equipped metal mask 40 including a metal mask 10 in which slits 15 are provided and a resin plate 30, the metal mask and the resin plate being stacked. When the resin plate-equipped metal mask 40 is prepared, first, the metal mask 10 in which the slits 15 are provided is prepared. Notably, details of the materials and the like of the metal mask 10 and the resin plate 30 are described alongside when a vapor deposition mask produced by a producing method of an embodiment of the present invention is described.

The metal mask 10 is constituted of metal, in which the slits 15 extending in the lengthwise direction and/or the crosswise direction are arranged. Openings 25 are formed at a position overlapping with the slits 15 in the resin plate constituting the resin plate-equipped metal mask 40 in a step mentioned later.

As a method of forming the metal mask 10 in which the slits 15 are provided, for example, the following method can be cited.

First, a masking member, for example, a resist material is applied onto the surface of a metal plate, predetermined portions thereof are exposed and developed, and thereby, a resist pattern in which positions where the slits 15 are finally to be formed remain is formed. The resist material used as the masking member is preferably excellent in processing ability with desired resolution. Next, etching processing is performed by an etching method using this resist pattern as an etching resistant mask. Next, after the completion of the etching, the resist pattern is cleaned and removed. In this way, the metal mask 10 in which the slits 15 are provided is obtained. The etching for forming the slits 15 may be performed on one surface side of the metal plate or may be performed on both surfaces thereof. Moreover, in the case where the slits 15 are formed in the metal plate using a stacked body in which the resin plate is provided on the metal plate, the masking member may be applied onto the surface of the metal plate on the side that is not in contact with the resin plate to form the slits 15 by the etching from one surface side. Notably, in the case where the resin plate has etching resistance with respect to the etching agent for the metal plate, masking of the surface of the resin plate is not needed. Meanwhile, in the case where the resin plate does not have resistance with respect to the etching agent for the metal plate, the masking member is needed to be applied onto the surface of the resin plate. Moreover, in the above, while the case where the resist material is used as the masking member is exemplarily described, in place of the application of the resist material, a dry film resist may be laminated to perform the similar patterning. Notably, the metal mask 10 constituting the resin plate-equipped metal mask 40 is not limited to one formed by the method exemplified above but can also employ a commercial product. Moreover, in place of the formation of the slits 15 by etching, the slits 15 can also be formed by irradiation with laser light.

A method of pasting the metal mask 10 and the resin plate 30 constituting the resin plate-equipped metal mask 40 together and a forming method thereof are not specially limited. For example, the resin plate-equipped metal mask 40 can also be obtained by beforehand preparing a stacked body formed by coating of a resin layer with respect to a metal plate to be the metal mask 10, and forming the slits 15 in the metal plate in the state of the stacked body. In the present embodiment, the resin plate 30 constituting the resin plate-equipped metal mask 40 includes not only a plate-like resin but also a resin layer and a resin film formed by coating as mentioned above. In other words, the resin plate 30 may be beforehand prepared or may be formed by a conventionally known coating method or the like. Moreover, the resin plate 30 is a concept including a resin film and a resin sheet. Moreover, the hardness of the resin plate 30 is not limited but it may be a hard plate or a soft plate. Moreover, the metal mask 10 and the resin plate 30 may be pasted together with various adhesive agents or the resin plate 30 that has self-adhesion may be used. Notably, the dimensions of the metal mask 10 and the resin plate 30 may be the same. Notably, with fixing of a vapor deposition mask 100 produced by the producing method of the present embodiment to a frame 50 taken into consideration, the dimension of the resin plate 30 may be made smaller than that of the metal plate 10 to set the outer circumferential portion of the metal mask 10 to be in the state of exposure, which facilitates welding of the metal mask 10 to the frame 50.

### (Step of Fixing to Frame)

Next, as shown in FIG. 1B, the metal mask 10 constituting the resin plate-equipped metal mask 40 is fixed to the frame 50. While in the present embodiment, this fixing step is an arbitrary step, since in the case of using the vapor deposition mask 100 in a typical vapor deposition apparatus, it is often fixed to the frame 50 to be used, this step is preferably performed in this timing. On the other hand, not shown in the figure, a fixing step of fixing the metal mask 10 at the prestage of the resin plate-equipped metal mask 40 to a frame may be performed, after that, to provide the resin plate 30. A method of fixing the metal mask 10 to the frame 50 is not specially limited but, for example, in the case where the frame 50 includes metal, a conventionally known step or method such as spot welding only has to be properly employed.

### (Step of Forming Openings in Resin Plate)

Next, as shown in FIG. 1C, openings corresponding to a pattern to be produced by vapor deposition are formed in the resin plate 30 by irradiation with a laser from the metal mask 10 side of the resin plate-equipped metal mask 40. The present embodiment is characterized in using a laser mask 70 as shown in the figure at this stage. Notably, while in FIG. 1C, the laser mask 70 is disposed spaced from the resin plate-equipped metal mask 40, it is not limited to this figure. For example, as shown in FIG. 13, a condenser lens 130 may be installed between the laser mask 70 and the resin plate-equipped metal mask 40 to form the openings by a so-called “laser processing method using a reducing projection optical system”.

The laser mask 70 is provided with opening regions 71 corresponding to patterns to be produced by vapor deposition, in other words, corresponding to openings formed in the final stage, and attenuating regions 72 that are positioned in the peripheries of the opening regions 71 and attenuate the energy of the laser of the irradiation. By using such a laser mask 70, as shown in FIG. 1D, openings 25 corresponding to the patterns to be produced by vapor deposition can be formed in the resin plate 30 with the laser that passes through the opening regions 71, and thin parts 26 not penetrating can be simultaneously formed in the peripheries of the openings 25 with the laser whose energy is attenuated by passing through the attenuating regions 72, affording the vapor deposition mask 100.

By forming the thin parts 26 in the peripheries of the openings 25, generation of a so-called shadow can be suppressed in the case where the patterns are produced by vapor deposition using the vapor deposition mask 100, which can improve pattern precision. Moreover, by simultaneously forming the openings 25 along with the thin parts 26 positioned in the peripheries thereof as in the present embodiment, dimensional precision can be dramatically improved.

Hereafter, the laser mask used in the method for producing a vapor deposition mask of the present embodiment is described using the figures.

### (Laser Mask)

FIG. 2 is an elevation view of the laser mask used in the method for producing a vapor deposition mask of the present embodiment.

As shown in FIG. 2, in the laser mask 70, the opening regions 71 corresponding to the patterns to be produced by vapor deposition, in other words, corresponding to the openings formed in the final stage, and the attenuating regions 72 that are positioned in the peripheries of the opening regions 71 and attenuate the energy of the laser of the irradiation are provided as described above using FIGS. 1A-1D.

Here, the opening regions 71 are not specially mentioned but through holes corresponding to patterns to be produced by vapor deposition or the like are the opening regions 71. Accordingly, the shape of the opening region 71 is not limited to be rectangular as shown in the figure but, when the pattern to be produced by vapor deposition is circular, the shape of the opening region 71 is also correspondingly circular in the nature of things, and when the pattern to be produced by vapor deposition is hexagonal, the shape of the opening region 71 is also hexagonal. Notably, while the transmittance of the laser in the opening region 71 is 100% when the opening region 71 is a through hole, it is not necessarily 100% but can be properly designed in its relative relation to the transmittance of the laser in the attenuating region 72 mentioned later. In other words, the “opening region 71” in an embodiment of the present invention is a region for forming an opening formed in a vapor deposition mask in the final stage, and the opening region 71 itself is not necessarily in the state of opening like a through hole. Accordingly, the effect can be achieved, for example, even when the transmittance of the laser in the opening region 71 is 70% and the transmittance of the laser in the attenuating region 72 mentioned later is 50%.

The attenuating regions 72 are formed for the purpose to form the thin parts 26 in the peripheries of the openings 25 of the resin plate 30 with the laser having passed through the attenuating regions 72 in timing when the openings 25 are formed in the resin plate 30 with the laser having passed through the opening regions 71, as shown in FIG. 1D, by them positioned in the peripheries of the opening regions 71 and attenuating the energy of the laser of the irradiation. Accordingly, a specific mode of the attenuating region 72 is not specially limited but it only has to be a mode in which the energy of the laser can be attenuated to an extent where thinness can be achieved without penetrating the resin plate 30 that is positioned in the periphery of the opening 25 in timing of the aforementioned effect, in other words, when the opening 25 is formed, and the transmittance of the laser in the attenuating region 72 is preferably set to be about 50% or less.

For example, as shown in FIG. 2, by forming through grooves 74 having opening widths smaller than a resolution of the laser of the irradiation concentrically in the periphery of the opening region 71, that is, forming so-called line-and-space, the relevant portion may be set to be the attenuating region 72. Since this through grooves 74 have the opening widths smaller than the value of the production of the “resolution of the laser” and a “reducing rate of the optical system of the laser processing apparatus”, the laser passing through the through grooves 74 is diffracted, as a result, laser travelling straight is reduced and the energy thereof is attenuated. Notably, the reducing rate of the optical system of the laser processing apparatus is calculated from (the size of the opening region on the laser mask)/(the size of the opening on the vapor deposition mask).

Here, the “resolution of the laser” in the present specification is the lower limit value of line-and-space that can be formed when the line-and-space constituted of through grooves is formed with respect to a resin plate as a processing target.

Here, the dimension of the attenuating region 72, in other words, the distance from the end side of the opening region 71 to the end side of the attenuating region 72 is not specially limited but it only has to be properly designed with the dimension of the thin part 26 to be formed in the periphery of the opening of the resin mask in the final stage and the distance between the openings 25 taken into consideration.

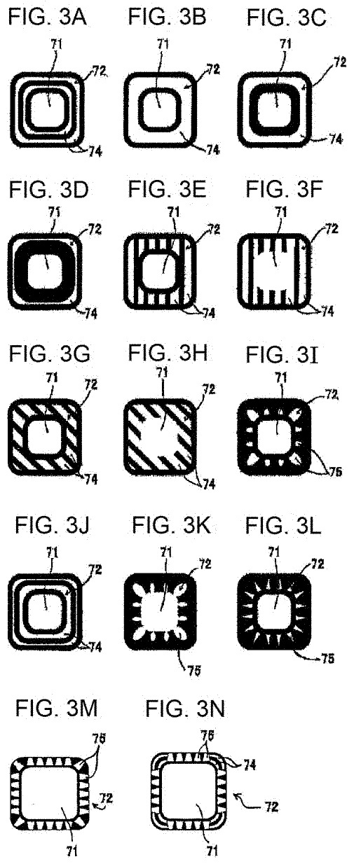

FIGS. 3A to 3N are expanded elevation views of various laser masks for explaining specific modes of the opening region and the attenuating region.

For example, as shown in FIGS. 3A to 3D and 3J, the attenuating region 72 may be disposed so as to form the through grooves 74 having opening widths smaller than the resolution of the laser of the irradiation concentrically in the periphery of the opening region 71, that is, to form so-called line-and-space. Notably, while in FIGS. 3A and 3J, two through grooves 74 are concentrically provided, the number of the through grooves 74 is not specially limited but may be two or more. Moreover, while all the through grooves 74 shown in FIGS. 3A to 3D and 3J exhibit rectangular shapes, they are not limited to these but may be concentric and wave-like.

Meanwhile, for example, as shown in FIGS. 3G to 3H, the through grooves 74 having opening widths smaller than the resolution of the laser of the irradiation may be arranged into an oblique stripe shape in the periphery of the opening region 71, and thereby, they may be set to be the attenuating region 72.

Furthermore, for example, as shown in FIGS. 31 and 3K to 3N, discontinuous through holes 75 having opening widths smaller than the resolution of the laser of the irradiation may be arranged in the periphery of the opening region, and thereby, they may be set to be the attenuating region 72. Notably, in FIG. 3N, both of the through grooves 74 and the through holes 75 are arranged.

Notably, the shapes of the through grooves 74 and the through holes 75 for forming the attenuating region 72 can be properly designed, they are not necessarily formed separate from the opening region 71, and as shown in FIGS. 3F, 3H and 3K, the through grooves 74 and the through holes 75 may be continuous to the opening region 71.

Moreover, as shown in FIGS. 31 to 3N, the opening widths of the through grooves 74 and the through holes 75 for forming the attenuating region 72 can be designed to become smaller as going away from the opening region 71, and thereby, the thickness of the thin part formed in the periphery of the opening of the resin mask can be changed in stages by the attenuating region 72.

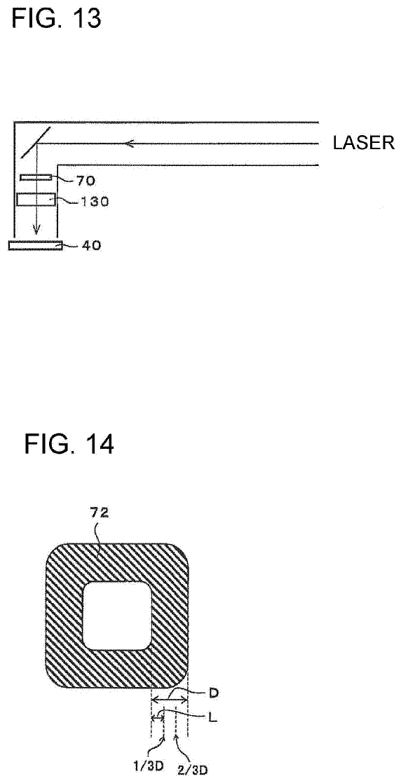

Moreover, as shown in FIG. 14, when the width of the attenuating region 72 is set to be D and the reducing rate of the optical system of the laser processing apparatus is a times, D/a is preferably set to be larger than about 1 μm and smaller than about 20 μm, further preferably larger than about 5 μm and smaller than about 10 μm. Moreover, for example, when the width of the attenuating region 72 is set to be D, the transmittance of the laser in a region from the boundary of the opening region 71 to ⅓D may be set to be 40%, the transmittance of the laser in a region from ⅓D to ⅔D to be 40%, and the transmittance of the laser in a region from ⅔D to D to be 30%.

Moreover, when the width of ⅓D in FIG. 14 is set to be L, the transmittance of the laser in a region from the boundary of the opening region 71 to ½L is preferably set to be smaller than the transmittance of the laser in a region from ½L to 2/2L. Specifically, the transmittance of the laser in the region from the boundary of the opening region 71 to ½L may be set to be 20%, and the transmittance of the laser in the region from ½L to 2/2L may be set to be 60%. In this way, the boundary between the opening region 71 and the attenuating region becomes definite, and an excellent pattern with high straightness at the edge of the opening of a vapor deposition mask can be obtained.

Moreover, while in the aforementioned description, the attenuating region 72 is constituted of the through grooves 74 or the through holes 75 having opening widths smaller than the value of the production of the “resolution of the laser” and the “reducing rate of the optical system of the laser processing apparatus”, embodiments of the present invention are not limited to this.

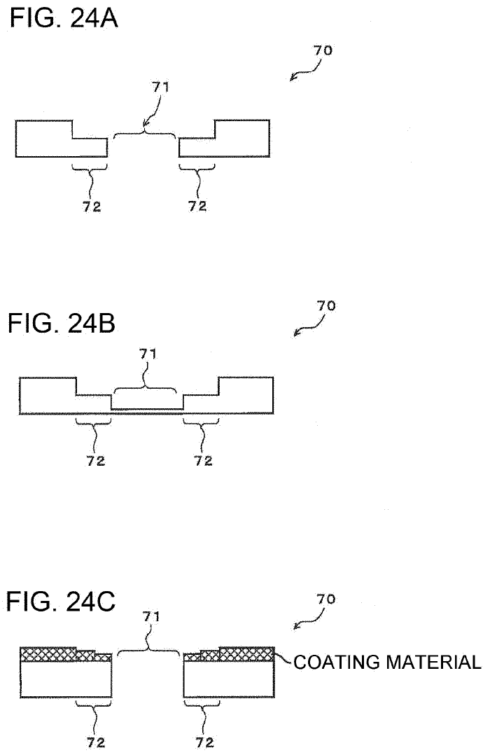

FIGS. 24A to 24C show cross-sectional views of laser masks according to an embodiment of the present invention.

As shown in FIG. 24A, the attenuating region 72 of the laser mask 70 may attenuate the energy of the laser of the irradiation by using a groove or a hole that does not penetrate in place of the through grooves 74 and the through holes 75 described above. In other words, the laser mask 70 shown in FIG. 24A has the opening region 71 that is constituted of a penetrating hole, and the attenuating region 72 that is positioned in the periphery thereof and is constituted of a groove or a hole that does not penetrate. According to such a laser mask 70, the energy of the laser of the irradiation onto the attenuating region 72 is attenuated while passing through the laser mask that is thin, and as a result, the thin part 26 can be formed in the resin plate 30.

Moreover, meanwhile, as shown in FIG. 24B, also the opening region 71 of the laser mask in FIG. 24A described above may be constituted of a hole that does not penetrate. Also in this case, due to a difference in energy of the laser passing through the opening region 71 and the attenuating region 72 between these regions, the opening 25 and the thin part 26 can be formed in the resin plate 30.

Furthermore, as shown in FIG. 24C, in place of the through grooves 74 and the through holes 75 in the attenuating region 72, the energy of the laser passing through the attenuating region 72 may be attenuated by applying a coating material that attenuates the energy of the laser. In other words, the laser mask 70 can be formed of a material that transmits laser to some extent to apply the coating material that attenuates the energy of the laser onto the periphery of the opening region 71 constituted of a penetrating hole into gradations, thereby, to form the attenuating region 72, and thereby, the opening 25 and the thin part 26 can be formed in the resin plate 30 due to the difference in energy of the laser passing through the opening region 71 and the attenuating region 72 between these regions. Notably, as the coating material that attenuates the energy of the laser, any of a coating material that absorbs laser and a coating material that reflects laser can be used.

### (Vapor Deposition Mask)

Hereafter, preferable modes of the vapor deposition mask are described. Notably, the vapor deposition mask described here is not limited to the modes described below but may be in any mode as long as a condition is satisfied that the metal mask in which the slit is formed is stacked on the resin mask in which the openings corresponding to a pattern to be produced by vapor deposition are formed at a position overlapping with the slit. For example, the slit formed in the metal mask may be stripe-shaped (not shown). Moreover, the slit of the metal mask may be provided at a position not overlapping with the whole one screen. This vapor deposition mask may be produced by the method for producing a vapor deposition mask according to an embodiment of the present invention described above, or may be produced by another method.

### (Vapor Deposition Mask of Embodiment (A))

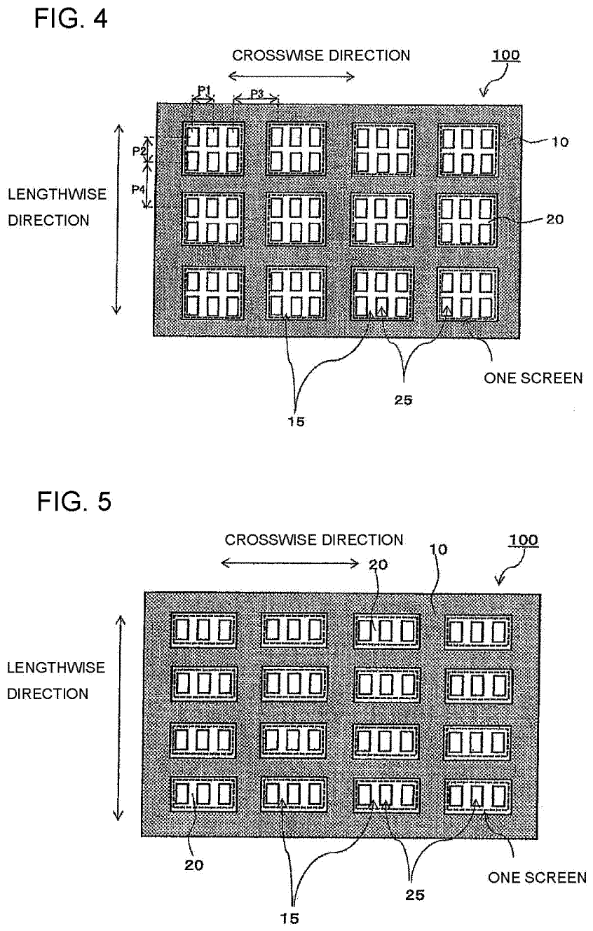

As shown in FIG. 4, the vapor deposition mask 100 of Embodiment (A) is a vapor deposition mask for simultaneously forming vapor deposition patterns for a plurality of screens and includes the metal mask 10 in which the plurality of slits 15 are provided and the resin mask 20, the metal mask being stacked on one surface of the resin mask, wherein the openings 25 needed for constituting the plurality of screens are provided in the resin mask 20, and each slit 15 is provided at a position overlapping with the entirety of at least one screen.

The vapor deposition mask 100 of Embodiment (A) is a vapor deposition mask used for simultaneously forming vapor deposition patterns for a plurality of screens. One vapor deposition mask 100 can simultaneously form vapor deposition patterns compatible with a plurality of products. “Openings” stated for the vapor deposition mask of Embodiment (A) mean patterns to be produced using the vapor deposition masks 100 of Embodiment (A). For example, when the vapor deposition mask is used for forming an organic layer in an organic EL display, the shape of the openings 25 is a shape of the organic layer. Moreover, “one screen” is constituted of an aggregate of openings 25 corresponding-to one product. When the one product is an organic EL display, an aggregate of organic layers needed for forming one organic EL display, in other words, an aggregate of openings 25 to be the organic layers is “one screen”. Further, in the vapor deposition mask 100 of Embodiment (A), in order to simultaneously form the vapor deposition patterns for the plurality of screens, the aforementioned “one screen” is arranged for each of the plurality of screens in the resin mask 20 at predetermined intervals. Namely, in the resin mask 20, the openings 25 needed for constituting the plurality of screens are provided.

The vapor deposition mask of Embodiment (A) includes the metal mask 10 in which the plurality of slits 15 are provided, the metal mask being provided on one surface of the resin mask, wherein each slit is provided at the position overlapping with the entirety of at least one screen. In other words, it is characterized in that between the openings 25 needed for constituting one screen, metal line portions which have the same length as the length of the slit 15 in the lengthwise direction and have the same thickness as that of the metal mask 10 between the openings 25 adjacent in the crosswise direction, or metal line portions which have the same length as the length of the slit 15 in the crosswise direction and have the same thickness as that of the metal mask 10 between the openings 25 adjacent in the lengthwise direction do not exist. Hereafter, the metal line portions which have the same length as the length of the slit 15 in the lengthwise direction and have the same thickness as that of the metal mask 10 and the metal line portions which have the same length as the length of the slit 15 in the crosswise direction and have the same thickness as that of the metal mask 10 are sometimes collectively referred to simply as metal line portions.

According to the vapor deposition mask 100 of Embodiment (A), even when the dimension of the openings 25 needed for constituting one screen and the pitch between the openings 25 constituting one screen are made small, for example, even when the dimension of the openings 25 and the pitch between the openings 25 are made extremely fine in order to form a screen exceeding 400 ppi, interference due to metal line portions can be prevented and an image with high definition can be formed. Accordingly, in the method for producing a vapor deposition mask according to the present embodiment, the vapor deposition mask is preferably produced so as to be Embodiment (A) in the final stage. Notably, when one screen is divided by a plurality of slits, in other words, when the metal line portions having the same thickness as that of the metal mask 10 exist between the openings 25 constituting one screen, as the pitch between the openings 25 constituting one screen is smaller, the metal line portions existing between the openings 25 more become a hindrance in forming the vapor deposition pattern on the vapor deposition target and the vapor deposition pattern with high definition is more difficult to be formed. In other words, when the metal line portions having the same thickness as that of the metal mask 10 exist between the openings 25 constituting one screen, the metal line portions in the case of setting the frame-equipped vapor deposition mask cause generation of a shadow, which results in difficulty of formation of a screen with high definition.

Next, referring to FIG. 4 to FIGS. 7A and 7B, the openings 25 constituting one screen are exemplarily described. Notably, a region enclosed by a broken line in the modes shown in the figures is one screen. While in the modes shown in the figures, an aggregate of a small number of openings 25 is one screen for convenience of description, not limited to these modes, for example, the openings 25 for millions of pixels may be present in one screen, where one opening 25 is one pixel.

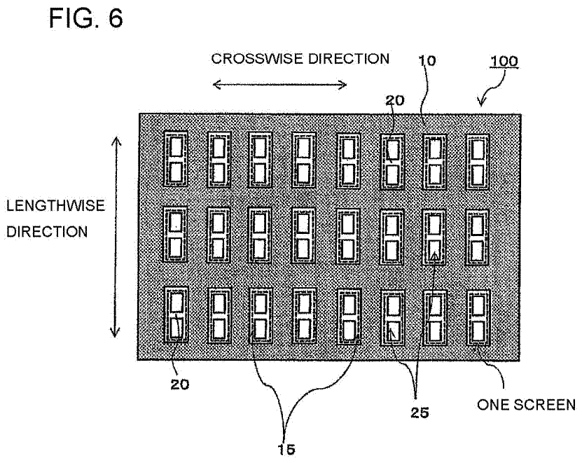

In the mode shown in FIG. 4, one screen is constituted of an aggregate of openings 25 having a plurality of openings 25 provided in the lengthwise direction and the crosswise direction. In the mode shown in FIG. 5, one screen is constituted of an aggregate of openings 25 having a plurality of openings 25 provided in the crosswise direction. Moreover, in the mode shown in FIG. 6, one screen is constituted of an aggregate of openings 25 having a plurality of openings 25 in the lengthwise direction. Further, in FIG. 4 to FIG. 6, the slit 15 is provided at a position overlapping with the entirety of one screen.

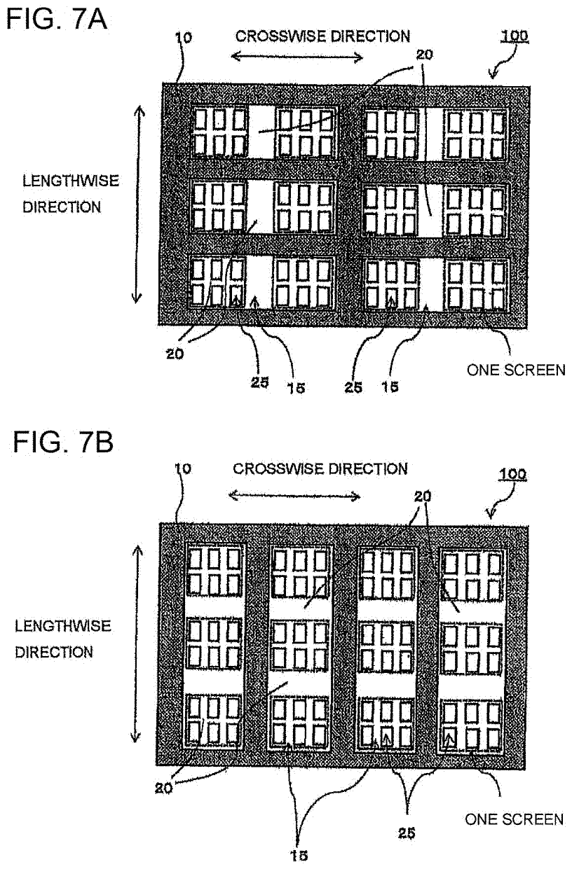

As described above, the slit 15 may be provided at a position overlapping with only one screen, or as shown in FIGS. 7A and 7B, may be provided at a position overlapping with the entirety of two or more screens. In FIG. 7A, in the resin mask 10 shown in FIG. 4, the slit 15 is provided at a position overlapping with the entirety of two screens continuous in the crosswise direction. In FIG. 7B, the slit 15 is provided at a position overlapping with the entirety of three screens continuous in the lengthwise direction.

Next, exemplified by the mode shown in FIG. 4, pitches between the openings 25 constituting one screen and pitches between the screens are described. The pitches between the openings 25 constituting one screen and the dimension of the opening 25 are not specially limited but can be properly set depending on the pattern to be produced by vapor deposition. For example, when forming the vapor deposition pattern with high definition of 400 ppi, a pitch (P1) in the crosswise direction and a pitch (P2) in the lengthwise direction between the neighboring openings 25 out of the openings 25 constituting one screen are about 60 μm. Moreover, the dimension of the opening is about 500 μm² to about 1000 μm². Moreover, one opening 25 is not limited to correspond to one pixel but, for example, a plurality of pixels can also be collectively one opening 25 depending on a pixel arrangement.

While a pitch (P3) in the crosswise direction and a pitch (P4) in the lengthwise direction between the screens are not specially limited but, as shown in FIG. 4, when one slit 15 is provided at the position overlapping with the entirety of one screen, metal line portions are to exist between the screens. Accordingly, when the pitch (P3) in the crosswise direction and the pitch (P4) in the lengthwise direction between the screens are smaller than or substantially equal to the pitch (P1) in the crosswise direction and the pitch (P2) in the lengthwise direction of the openings 25 provided in one screen, the metal line portions existing between the screens are liable to break. Accordingly, with this point taken into consideration, the pitch (P3, P4) between the screens is preferably wider than the pitch (P1, P2) between the openings 25 constituting one screen. The pitch (P3, P4) between the screens is exemplarily about 1 mm to about 100 mm. Notably, the pitch between the screens means the pitch between the neighboring openings in one screen and another screen adjacent to the one screen. The same holds true for the pitch between the openings 25 and the pitch between the screens in the vapor deposition mask of Embodiment (B) mentioned later.

Notably, as shown in FIGS. 7A and 7B, when one slit 15 is provided at the position overlapping with the entirety of two or more screens, metal line portions constituting the inner wall surfaces of the slit are not to exist between the plurality of screens provided in the one slit 15. Accordingly, in this case, the pitch between the two or more screens provided at the position overlapping with the one slit 15 may be substantially equal to the pitch between the openings 25 constituting one screen.

### (Vapor Deposition Mask of Embodiment (B))

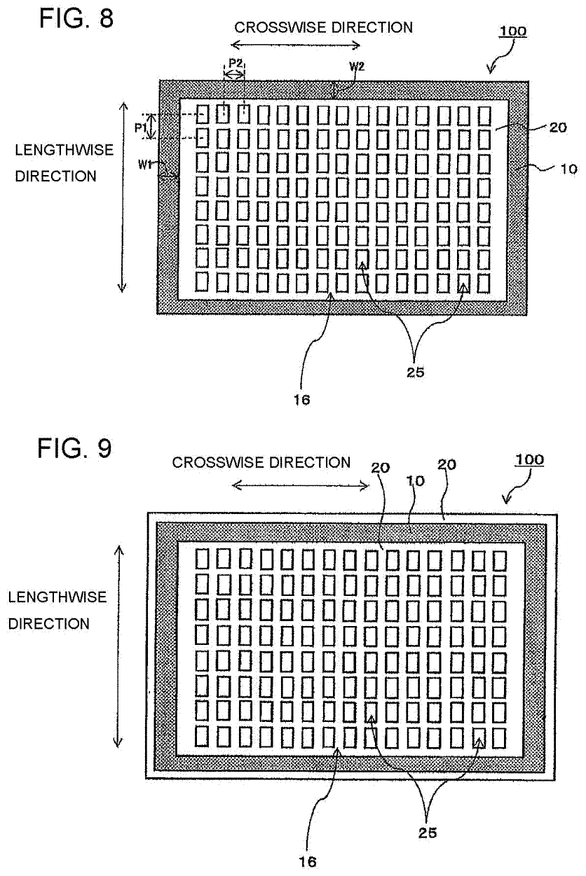

Next, the vapor deposition mask of Embodiment (B) is described. As shown in FIG. 8, the vapor deposition mask of Embodiment (B) includes the metal mask 10 in which one slit 16 (one through hole) is provided and the resin mask 20 in which the plurality of openings 25 corresponding to a pattern to be produced by vapor deposition are provided, the metal mask being stacked on one surface of resin mask, wherein all of the plurality of openings 25 are provided at a position overlapping with the one through hole provided in the metal mask 10.

The opening 25 stated for Embodiment (B) means an opening needed for forming the vapor deposition pattern on the vapor deposition target. An opening not needed for forming the vapor deposition pattern on the vapor deposition target may be provided at a position of not overlapping with the one slit 16 (the one through hole). Notably, FIG. 8 is an elevation view which exemplarily shows the vapor deposition mask of Embodiment (B) and is of the vapor deposition mask as seen from the metal mask side.

In the vapor deposition mask 100 of Embodiment (B), the metal mask 10 having the one through hole 16 is provided on the resin mask 20 having the plurality of openings 25, and all of the plurality of openings 25 are provided at a position overlapping with the one slit 16 (the one through hole). In the vapor deposition mask 100 of Embodiment (B) that has this configuration, metal line portions that have the same thickness as the thickness of the metal mask or a larger thickness than the thickness of the metal mask do not exist between the openings 25. Hence, as described for the aforementioned vapor deposition mask of Embodiment (A), the vapor deposition pattern with high definition can be formed to match the dimensions of the openings 25 provided in the resin mask 20 without suffering interference of metal line portions.

Moreover, according to the vapor deposition mask of Embodiment (B), there is almost no influence of a shadow even when the thickness of the metal mask 10 is made large. Hence, the thickness of the metal mask 10 can be made larger to such an extent that durability and handling ability are sufficiently satisfied. While a vapor deposition pattern with high definition can be formed, durability and handling ability can be improved. Accordingly, in the method for producing a vapor deposition mask of an embodiment, the vapor deposition mask is preferably produced so as to be Embodiment (B) in the final stage.

The resin mask 20 in the vapor deposition mask of Embodiment (B) is constituted of resin, in which as shown in FIG. 8, the plurality of openings 25 corresponding to a pattern to be produced by vapor deposition are provided at a position overlapping with the one slit 16 (the one through hole). The openings 25 correspond to the pattern to be produced by vapor deposition. By a vapor deposition material released from a vapor deposition source passing through the openings 25, the vapor deposition pattern corresponding to the openings 25 is formed on the vapor deposition target. Notably, while in the mode shown in the figure, the openings arranged in a plurality of rows in the lengthwise direction and the crosswise direction are exemplarily described, they may be arranged only in the lengthwise direction or in the crosswise direction.

“One screen” in the vapor deposition mask 100 of Embodiment (B) means an aggregate of openings 25 corresponding to one product. When the one product is an organic EL display, an aggregate of organic layers needed for forming one organic EL display, in other words, an aggregate of openings 25 to be the organic layers is “one screen”. While the vapor deposition mask of Embodiment (B) may be constituted of only “one screen” or may be provided by arranging the “one screen” for each of a plurality of screens, in the case where the “one screen” is arranged for each of the plurality of screens, the openings 25 are preferably provided at predetermined intervals on a screen-by-screen basis (refer to FIG. 6 for the vapor deposition mask of Embodiment (A)). The mode of “one screen” is not specially limited but, for example, the one screen can also be constituted of millions of openings 25, where one opening 25 is one pixel.

The metal mask 10 in the vapor deposition mask 100 of Embodiment (B) is constituted of metal and includes the one slit 16 (the one through hole). Further, in the vapor deposition mask of Embodiment (B), the one slit 16 (the one through hole) is disposed at a position overlapping with all of the openings 25 as seen head-on of the metal mask 10, in other words, at a position where all of the openings 25 arranged in the resin mask 20 can be seen.

The metal portion constituting the metal mask 10, that is, the portion thereof other than the one slit 16 (the one through hole) may be provided along the outer edge of the vapor deposition mask 100 as shown in FIG. 8, or the dimension of the metal mask 10 may be made smaller than that of the resin mask 20 to expose an outer circumferential portion of the resin mask 20 as shown in FIG. 9. Moreover, the dimension of the metal mask 10 may be made larger than that of the resin mask 20, so that a part of the metal portion is caused to protrude outward in the crosswise direction of the resin mask or outward in the lengthwise direction thereof. Notably, in any cases, the dimension of the one slit 16 (the one through hole) is configured to be smaller than the dimension of the resin mask 20.

While a width (W1), in the crosswise direction, and a width (W2), in the lengthwise direction, of the metal portion constituting the wall surface of the through hole of the metal mask 10 shown in FIG. 8 are not specially limited, as the width W1, W2 is made smaller, durability and handling ability tend to deteriorate more. Accordingly, W1 and W2 are preferably widths by which durability and handling ability are sufficiently satisfied. While appropriate widths can be properly set depending on the thickness of the metal mask 10, as an example of preferable widths, both W1 and W2 are about 1 mm to about 100 mm, which are the same widths of the metal mask of Embodiment (A).

Moreover, while in the vapor deposition mask of each embodiment described above, the openings 25 are regularly formed in the resin mask 20, the openings 25 may be alternately arranged in the crosswise direction or the lengthwise direction as seen from the metal mask 10 side of the vapor deposition mask 100 (not shown). In other words, the openings 25 adjacent in the crosswise direction may be displaced and arranged in the lengthwise direction. In such an arrangement, even in the case of thermal expansion of the resin mask 20, the openings 25 can absorb expansions arising in portions therein, and a large deformation due to accumulation of the expansions can be prevented from arising.

Moreover, in the vapor deposition mask of each embodiment described above, on the resin mask 20, grooves (not shown) extending in the lengthwise direction or the crosswise direction of the resin mask 20 may be formed. While in the case of application of heat in vapor deposition, there is a possibility that the resin mask 20 undergoes thermal expansion, and thereby, changes in dimension and position of the opening 25 arise, by forming the grooves, they can absorb the expansion of the resin mask, and can prevent the changes in dimension and position of the opening 25 caused by the resin mask 20 expanding in a predetermined direction as a whole due to accumulation of thermal expansions arising in portions in the resin mask. Formation positions of the grooves are not limited but while they may be provided between the openings 25 constituting one screen and at positions overlapping with the openings 25, they are preferably provided between the screens. Moreover, the grooves may be provided on one surface of the resin mask, for example, only on the surface on the side that is in contact with the metal mask, or may be provided only on the surface on the side that is not in contact with the metal mask. Otherwise, they may be provided on both surfaces of the resin mask 20.

Moreover, the grooves extending in the lengthwise direction may be between the neighboring screens, or the grooves extending in the crosswise direction may be formed between the neighboring screens. Furthermore, the grooves can also be formed in an aspect having these combined.

The depth and the width of the grooves are not specially limited but since the rigidity of the resin mask 20 tends to decrease in the case where the depth of the grooves is too large and in the case where the width thereof is too large, setting is needed with this point taken into consideration. Moreover, the sectional shape of the grooves is not specially limited but only has to be arbitrarily selected as a U-shape, a V-shape or the like with the processing method and the like taken into consideration. The same holds true for the vapor deposition mask of Embodiment (B).

### (Vapor Deposition Mask of Embodiment (C))

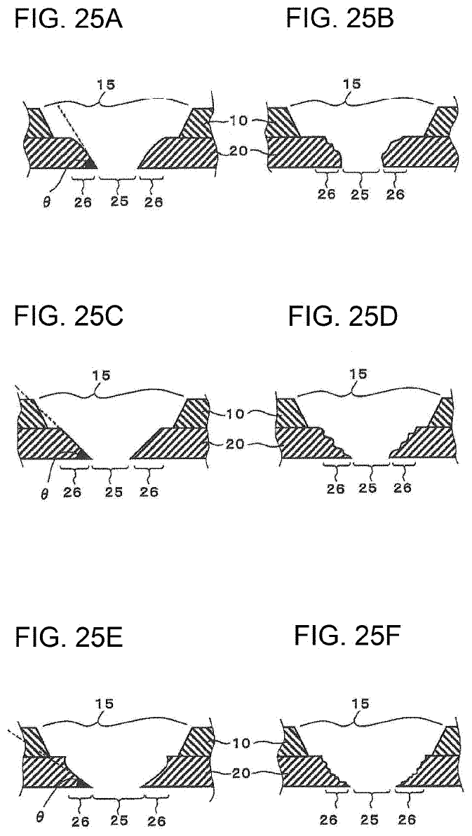

Next, a vapor deposition mask of Embodiment (C) is described. FIG. 25A to 25F show cross-sectional views of the vapor deposition mask of Embodiment (C).

As shown in FIG. 25A, the vapor deposition mask 100 of Embodiment (C) includes the metal mask 10 in which the slit 15 is provided and the resin mask 20 in which the opening 25 corresponding to a pattern to be produced by vapor deposition is provided, the metal mask and the resin mask being stacked, and the thin part 26 is formed in the periphery of the opening 25 in the resin mask 20. Further, it is characterized in that the sectional shape of the thin part 26 is an upwardly convex arc-shape. By forming the sectional shape of the thin part 26 in this way, the value of an angle θ formed by the sidewall of the opening 25 in the resin mask 20, more accurately, the tangential line of the sidewall and the bottom surface of the resin mask 20 can be made large, durability of the thin part 26 can be improved, and breakage and deformation of the thin part 26 can be prevented.

Notably, the sectional shape of the thin part 26 may be an upwardly convex arc-shape as a whole including some roughness as shown in FIG. 25B, not a clean upwardly convex arc-shape.

Moreover, meanwhile, as shown in FIG. 25C, the sectional shape of the thin part 26 may be a taper shape constituted of straight lines, and also in this case, as shown in FIG. 25D, it may include some roughness.

Furthermore, as shown in FIG. 25E, the sectional shape of the thin part 26 may be a downwardly convex arc-shape, and also in this case, as shown in FIG. 25F, it may include some roughness. Such a downwardly convex arc-shape can reduce influence of a so-called shadow.

Notably, a method for producing the vapor deposition masks of Embodiment (C) shown in FIGS. 25A to 25F is not specially limited but they can also be produced by using the method for producing a vapor deposition mask according to an embodiment of the present invention described above and adjusting the dimension and the shape of the attenuating region 72 in the laser mask 70.

### (Vapor Deposition Mask Producing Apparatus)

Next, a vapor deposition mask producing apparatus according to an embodiment of the present invention is described. The vapor deposition mask producing apparatus according to the present embodiment is characterized in that the laser mask used in (Method for Producing Vapor Deposition Mask) described above is used. Accordingly, for the other parts, individual configurations of a conventionally known vapor deposition mask producing apparatus only have to be properly selected and used. According to the vapor deposition mask producing apparatus according to the present embodiment, similarly to (Method for Producing Vapor Deposition Mask) described above, in an opening forming machine that irradiates a resin plate-equipped metal mask including a metal mask in which a slit is provided and a resin plate, the metal mask and the resin plate being stacked, with a laser from the metal mask side to form an opening corresponding to a pattern to be produced by vapor deposition in the resin plate, wherein by using a laser mask in which an opening region corresponding to the opening and an attenuating region that is positioned in the periphery of the opening region and attenuates the energy of the laser of the irradiation, the opening corresponding to the pattern to be produced by vapor deposition can be formed in the resin plate with the laser that passes through the opening region, and a thin part can be formed in the periphery of the opening of the resin plate with the laser that passes through the attenuating region.

### (Method for Producing Organic Semiconductor Element)

Next, a method for producing an organic semiconductor element according to an embodiment of the present invention is described. The method for producing an organic semiconductor element according to the present embodiment is characterized in that the vapor deposition mask produced by the method for producing a vapor deposition mask according to the present embodiment described above is used. Accordingly, detailed description of the vapor deposition mask is herein omitted.

The method for producing an organic semiconductor element according to the present embodiment includes an electrode forming step of forming electrodes on a substrate, an organic layer forming step, a counter electrode forming step, a sealing layer forming step and the like, and in any of the steps, a vapor deposition pattern is formed on the substrate in a vapor deposition method using the vapor deposition mask. For example, in the case where the vapor deposition method using the vapor deposition mask is applied to each of light-emitting layer forming steps for colors of R, G and B in an organic EL device, vapor deposition patterns are formed for the light-emitting layers for the colors on the substrate. Notably, the method for producing an organic semiconductor element according to the present embodiment is not limited to these steps but can be applied to any steps in conventionally known production of an organic semiconductor element using a vapor deposition method.

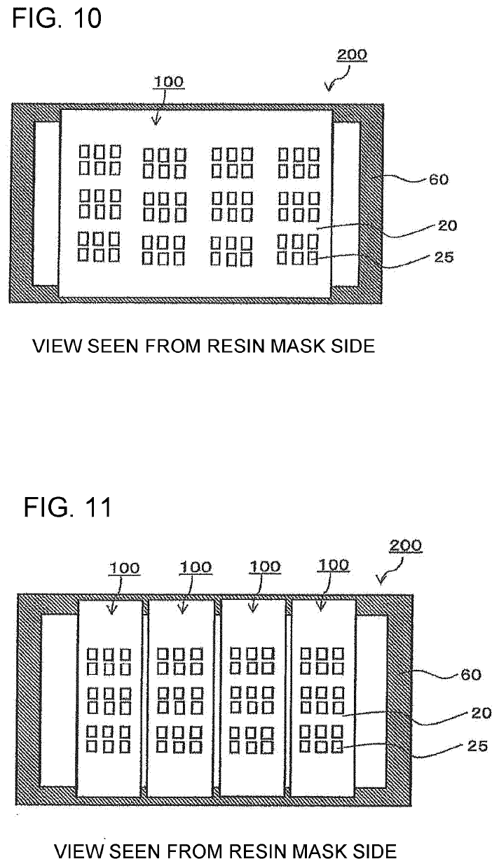

In the frame-equipped vapor deposition mask 200 used in the step of forming the vapor deposition pattern, as shown in FIG. 10, one vapor deposition mask 100 may be fixed to the frame 60, or as shown in FIG. 11, a plurality of vapor deposition masks 100 may be fixed to the frame 60.

The frame 60 is a substantially rectangular frame member and includes a through hole for exposing the openings 25 provided in the resin mask 20 of the vapor deposition mask 100 fixed in the final stage to the vapor deposition source side. The material of the frame is not specially limited but a metal material large in rigidity, for example, a SUS or invar material or a ceramic material or the like can be used. Above all, a metal frame is preferable in view of being able to easily perform welding to the metal mask of the vapor deposition mask and being small in influence of deformation and the like.

The thickness of the frame is not specially limited but is preferably about 10 mm to 30 mm in view of rigidity and the like. The widths of the inner circumferential end face of the opening of the frame and the outer circumferential end face of the frame are not specially limited as long as they are widths with which the frame and the metal mask of the vapor deposition mask can be fixed to each other, but, for example, widths of about 10 mm to 70 mm can be exemplarily cited.

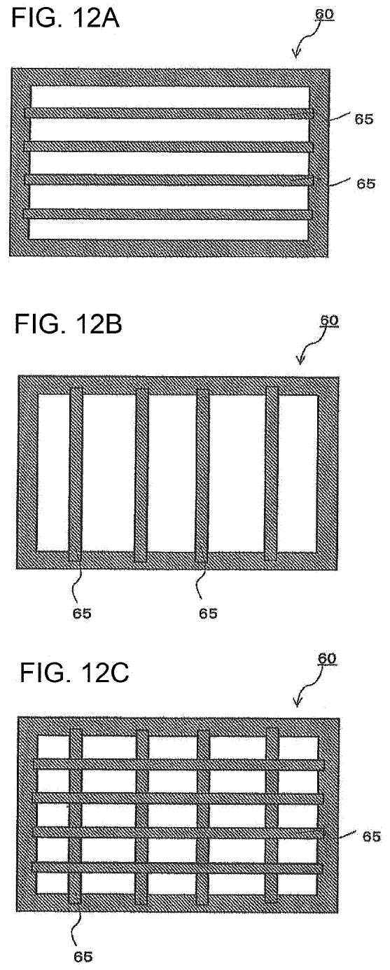

Moreover, as shown in FIGS. 12A to 12C, the frame 60 in which reinforcement frames 65 and the like are provided in the region of the through hole may be used so as not to disturb exposure of the openings 25 of the resin mask 20 constituting the vapor deposition mask 100. In other words, a configuration in which the opening included in the frame 60 is divided by the reinforcement frames and the like may be included. To provide the reinforcement frames 65 enables the frame 60 and the vapor deposition mask 100 to be fixed to each other using the relevant reinforcement frames 65. Specifically, when a plurality of vapor deposition masks 100 described above are arranged and fixed in the lengthwise direction and the crosswise direction, the vapor deposition masks 100 can be fixed to the frame 60 also at positions where the reinforcement frames and the vapor deposition masks overlap with each other.

According to the method for producing an organic semiconductor element according to the present embodiment, since the thin part 26 is formed in the periphery of the opening 25 of the vapor deposition mask 100 used, when a pattern is produced by vapor deposition, generation of a so-called shadow can be suppressed, and pattern precision can be improved.

As organic semiconductor elements produced in the method for producing an organic semiconductor element according to the embodiment, for example, organic layers, light-emitting layers, cathode electrodes and the like of organic EL elements can be cited. In particular, the method for producing an organic semiconductor element of an embodiment can be preferably used for production of R, G and B light-emitting layers of organic EL elements which require pattern precision with high definition.

### EXAMPLES

Hereafter, examples are presented.

### Example 1

A polyimide resin plate with about 5 μm of thickness was prepared, and using a laser mask according to Example 1 which had features presented in Table 1 below, openings and thin parts were formed in the polyimide resin plate. Notably, laser used in forming the openings and the thin parts was excimer laser with 248 nm of wavelength.

### Examples 2 to 9

In the same way as in Example 1 above, using laser masks according to Examples 2 to 9 which had features presented in Table 1 below, openings and thin parts were formed in the polyimide resin plates.

TABLE 1

| | Example 1 | Example 2 | Example 3 | Example 4 | Example 5 | Example 6 | Example 7 | Example 8 | Example 9 |
|---|---|---|---|---|---|---|---|---|---|
| Type of Laser | (n) | (c) | (n) | (n) | (l) | (a) | (a) | (a) | (j) |
| Mask (See | | | | | | | | | |
| Signs in FIG. 3) | | | | | | | | | |
| D/a (μm) | 7.5 | 5 | 7.5 | 5 | 5 | 7.5 | 7.5 | 5 | 5 |
| Transmittance | 17 | 20 | 31 | 33 | 34 | 37 | 37 | 41 | 46 |
| of Entirety of | | | | | | | | | |
| Attenuating | | | | | | | | | |
| Region (%) | | | | | | | | | |
| Transmittance | 33 | 0 | 58 | 54 | 53 | 42 | 42 | 42 | 42 |
| from Boundary | | | | | | | | | |
| to 1/3D (%) | | | | | | | | | |
| Transmittance | 20 | 60 | 35 | 41 | 42 | 40 | 29 | 50 | 48 |
| from 1/3D to | | | | | | | | | |
| 2/3D (%) | | | | | | | | | |
| Transmittance | 5 | 0 | 10 | 12 | 12 | 31 | 40 | 32 | 46 |
| from 2/3D to | | | | | | | | | |
| D (%) | | | | | | | | | |

Notably, D in Table 1 above is the length of the width of the attenuating region (see FIG. 14).

Moreover, a in Table 1 above is a reducing rate=(the size of the opening region on the laser mask)/(the size of the opening on the vapor deposition mask).

### (Results)

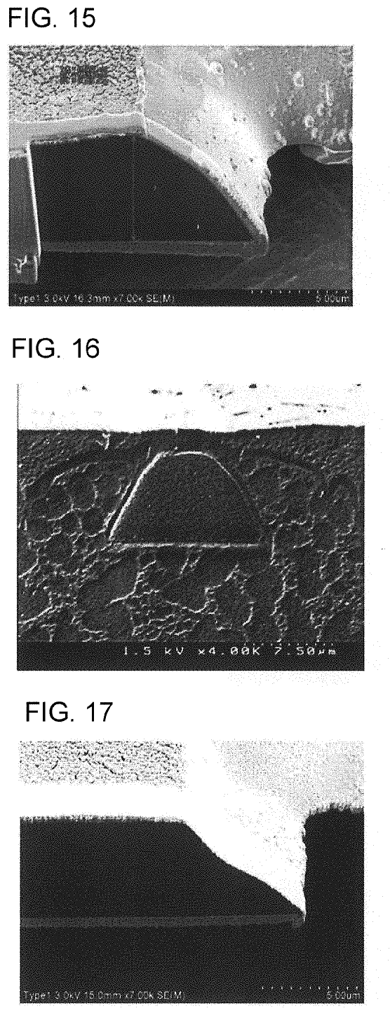

FIGS. 15 to 23 are sectional pictures of the polyimide resin plates in which the openings and the thin parts were formed using the respective laser masks according to Examples 1 to 9 above.

Moreover, the results of the formations of the openings and the thin parts in the polyimide resin plates using the laser masks according to Examples 1 to 9 above are collectively presented in Table 2 below.

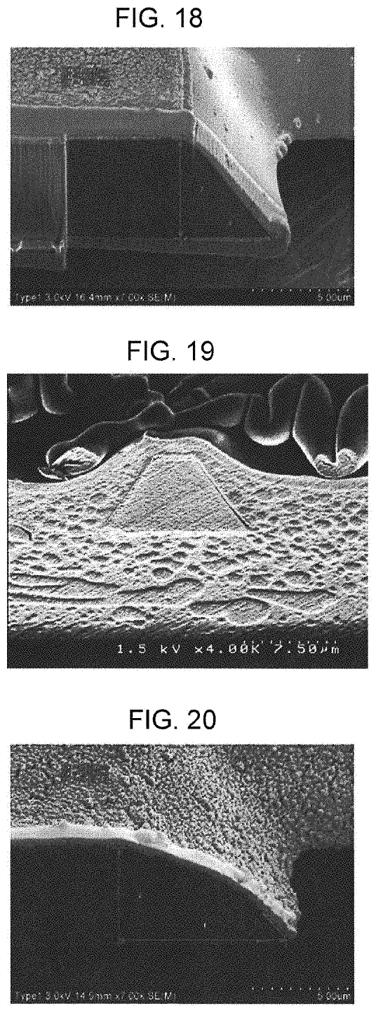

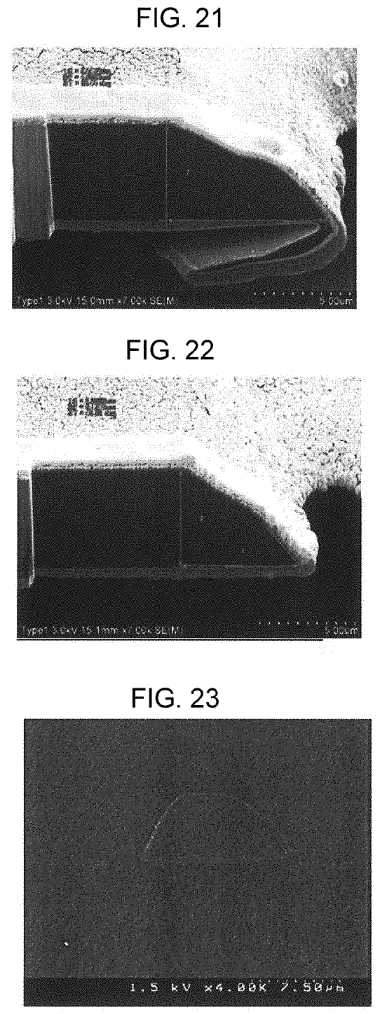

TABLE 2

| | Example 1 | Example 2 | Example 3 | Example 4 | Example 5 | Example 6 | Example 7 | Example 8 | Example 9 |
|---|---|---|---|---|---|---|---|---|---|
| Figure | FIG. 15 | FIG. 16 | FIG. 17 | FIG. 18 | FIG. 19 | FIG. 20 | FIG. 21 | FIG. 22 | FIG. 23 |
| Number of | | | | | | | | | |
| Sectional | | | | | | | | | |
| Picture | | | | | | | | | |
| Shape of | Upwardly | Upwardly | Downwardly | Straight Line - | Straight Line - | Upwardly | Steps | Steps - | Upwardly |
| Cross- | Convex | Convex Arc | Convex Arc | Downwardly | Downwardly | Convex Arc | | Upwardly | Convex Arc |
| Section | Arc | | | Convex Arc | Convex Arc | | | Convex Arc | |
| Taper Angle | 60 | 65 | 45 | 55 | 55 | 50 | 50 | 50 | 60 |
| in Cross- | | | | | | | | | |
| Section (°) | | | | | | | | | |

Notably, the “Taper Angle (°) in Cross-Section” in Table 2 above is the angle formed by the sidewall of the opening formed in the polyimide resin plate and the bottom surface in each of FIGS. 15 to 23.

Notably, when the shape of the sidewall of the opening formed in the polyimide resin plate is a curve like an upwardly convex arc-shape, it is the angle formed by the tangential line and the bottom surface.

As apparent from the sectional pictures in FIGS. 15 to 23 and Table 2 above, according to the laser masks of Examples 1 to 9, the type of the laser mask, in other words, the positions and the dimensions of the through grooves and the through holes in the attenuating region, and the transmittance of laser caused by these can be arbitrarily designed, and in accordance with the design, various shapes of thin parts can be formed around the openings.

For example, as shown in FIGS. 15, 16, 20 and 23, the sectional shape of the thin part can be set to be an upwardly convex arc. By setting the thin part to have such a shape, durability of the thin part can be improved, and breakage and deformation of the thin part can be prevented.

Meanwhile, as shown in FIGS. 17 to 19, the sectional shape of the thin part can also be set to be a shape close to a straight line from a downwardly convex arc. By setting the thin part to have such a shape, influence of a so-called shadow can be suppressed low.

Moreover, meanwhile, as shown in FIGS. 21 and 22, the sectional shape of the thin part can also be set to be a step-like shape.

### REFERENCE SIGNS LIST

10 Metal mask
15, 16 Slit
20 Resin mask
25 Opening
26 Thin part
30 Resin plate
40 Resin plate-equipped metal mask
50, 60 Frame
70 Laser mask
71 Opening region
72 Attenuating region
74 Through groove
75 Through hole
100 Vapor deposition mask

1. A method for producing a vapor deposition mask, comprising:
a step of preparing a resin plate-equipped metal mask including a metal mask in which a slit is provided and a resin plate, the metal mask and the resin plate being stacked; and
a step of performing irradiation with a laser from the metal mask side to form an opening corresponding to a pattern to be produced by vapor deposition in the resin plate, wherein
in the step of forming the opening,
by using a laser mask in which
an opening region corresponding to the opening, and
an attenuating region that is positioned in a periphery of the opening region and attenuates energy of the laser of the irradiation are provided,
the opening corresponding to the pattern to be produced by vapor deposition is formed with respect to the resin plate with the laser that passes through the opening region, and a thin part is formed in a periphery of the opening of the resin plate with the laser that passes through the attenuating region.

2. The method for producing a vapor deposition mask according to claim 1, wherein a transmittance of the laser in the attenuating region of the laser mask used in the step of forming the opening is about 50% or less.

3. A method for producing an organic semiconductor element, comprising
a vapor deposition pattern forming step of forming a vapor deposition pattern on a vapor deposition target using a vapor deposition mask, wherein
in the vapor deposition pattern forming step, the vapor deposition mask produced by the method for producing a vapor deposition mask according to claim 1 is used.
